(19) United States
(12) Patent Application Publication
(10) Pub. No.: US 2008/0093597 A1
(43) Pub. Date: Apr. 24, 2008

(54) SEMICONDUCTOR DEVICE

(75) Inventor: Goro KIYOTA, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY, INC., Tokyo (JP)

(21) Appl. No.: 11/875,146

(22) Filed: Oct. 19, 2007

(30) Foreign Application Priority Data
Oct. 24, 2006 (JP) 2006-288727

(51) Int. Cl. H01L 23/58; G01R 31/02

(52) U.S. Cl. 257/48; 324/755; 257/E23.141

(57) ABSTRACT

A semiconductor device is provided in which function modes thereof can be changed without difficulty and failure analysis can be conducted in an apparatus in which the semiconductor device is mounted. A semiconductor device uses a ball grid array package and includes: a semiconductor chip that is provided within the semiconductor device and has a pad; a detection via hole connected to the pad; a solder ball that is attachable to and detachable from the detection via hole and connects or disconnects a power supply electrode of a substrate on which the semiconductor device is mounted and the detection via hole in correspondence to attachment or detachment of the solder ball to or from detection via hole, respectively; and a mode switching unit that detects a voltage level of the pad connected to the detection via hole and switches function modes in the semiconductor device depending on the voltage level.

### BACKGROUND OF THE INVENTION

1. Field of the Invention

The present invention relates to a semiconductor device which is capable of switching between a plurality of function modes provided therein.

Priority is claimed on Japanese Patent Application No. 2006-288727, filed Oct. 24, 2006, the contents of which are incorporated herein by reference.

2. Description of Related Art

In the related art, there are semiconductor devices which are fixed to one of two operation modes when they are shipped.

Examples of such semiconductor devices may include a semiconductor device which selects one of two operation modes depending on whether to bond a pin to a lead wire, to which a power supply voltage is applied, using a bonding option (for example, see Japanese Unexamined Patent Application, First Publication No. 2004-47720 (hereinafter referred to as “Patent Document 1”)).

In addition, there are semiconductor devices which select one of two operation modes using an anti-fuse provided therein, not a bonding option (for example, see Japanese Unexamined Patent Application, First Publication No. 2003-168734 (hereinafter referred to as “Patent Document 2”) and Japanese Unexamined Patent Application, First Publication No. 2005-276907 (hereinafter referred to as “Patent Document 3”)).

However, the semiconductor device disclosed in Patent Document 1 has a problem in that the semiconductor device is fixed to any one of a group of operation modes when it is shipped and thereafter it is not possible to change the semiconductor device from the fixed operation mode to a different operation mode.

Moreover, the semiconductor devices disclosed in Patent Documents 2 and 3 have a problem in that, once the operation modes of the semiconductor devices are fixed, the operation modes cannot be changed since the anti-fuse is an irreversible conversion component.

Furthermore, in some cases, there may be a need to test semiconductor devices with their function switched, e.g., their internal power supply voltages, delay values of signals, or the like changed, for failure analysis.

In the case of testing using a tester, the tester provides a semiconductor device with a command to switch the semiconductor device into a test mode without difficulty. However, if it is determined that the semiconductor device is defective after it is mounted in an apparatus, the semiconductor device cannot be easily switched to the test mode unlike the test using the tester.

For example, in the case where the function mode (operation mode) is switched by means of the bonding option as disclosed in Patent Document 1, if the function of the semiconductor device, which is molded (sealed) with resin, is to be switched again, the function has to be switched after the resin is dissolved using a solvent. This may cause the semiconductor device to be damaged, which may lead to circuit analysis becoming impossible due to circuit breakage in some cases.

In addition, in the case of using the anti-fuse as disclosed in Patent Documents 2 and 3, since a circuit to drive the anti-fuse is required, the circuit scale and the chip area increase. Moreover, in the semiconductor devices as disclosed in Patent Documents 2 and 3, the function of the semiconductor devices can only be changed once, and thus cannot be used for failure analysis.

In addition, in the case where test mode registers are provided within the semiconductor device and switching between a plurality of test modes is performed, the software in the apparatus is required to be changed. However, it is difficult or almost impossible to do so because the software in the apparatus is produced by a customer.

### SUMMARY OF THE INVENTION

The present invention has been made in view of the foregoing problems, and an object of the present invention is to provide a semiconductor device in which function modes of the semiconductor device can be changed without difficulty and failure analysis can be conducted in an apparatus in which the semiconductor device is mounted.

A semiconductor device in accordance with the present invention uses a ball grid array package, and comprises: a semiconductor chip that is provided within the semiconductor device and has a pad; a detection via hole connected to the pad; a solder ball that is attachable to and detachable from the detection via hole and connects or disconnects a power supply electrode of a substrate on which the semiconductor device is mounted and the detection via hole in correspondence to attachment of the solder ball to the detection via hole or detachment of the solder ball from the detection via hole, respectively; and a mode switching unit that detects a voltage level of the pad connected to the detection via hole and switches a plurality of function modes in the semiconductor device depending on the voltage level.

In the semiconductor device, the detection via hole may be an external power supply via hole to which power is supplied from the outside of the package.

The semiconductor device may further comprise a mode via hole for function mode selection, and the mode switching unit may switch the function modes by selecting one of the plurality of function modes in accordance with a voltage level of the mode via hole.

In the semiconductor device, the mode via hole may be a via hole for non-connection.

In the semiconductor device, the mode via hole may be provided in the circumference of the semiconductor device.

A mode switching method for a semiconductor device using a ball grid array package in accordance with the present invention, comprises: attaching or detaching a solder ball to or from a detection via hole connected to a pad of a semiconductor chip provided within the semiconductor device, and connecting or disconnecting a power electrode of a substrate on which the semiconductor device is mounted and the detection via hole; and detecting a voltage level of the detection via hole, and switching a plurality of function modes in the semiconductor device depending on the voltage level.

In accordance with the present invention, function modes provided in a ball grid array (BGA) package can be switched by detaching or attaching one or more solder balls mounted in one or more external power supplies via holes (that is, via holes to which power is supplied from the outside of the semiconductor device).

In addition, a non-connection (NC) pin or the like, which is normally not used, may be used for selection of the function modes. This allows failure analysis to be conducted with the semiconductor device mounted in an apparatus. Accordingly, for example, the switching of function modes which is required for failure analysis of the semiconductor device can be conducted by inputting a signal through the NC pin.

This can suppress increases in the circuit scale and the chip area when the function modes of the semiconductor device are switched for failure analysis, as compared with conventional anti-fuses.

In addition, in accordance with the present invention, the semiconductor device does not suffer damage due to dissolution of resin with a solvent, unlike conventional bonding options, and the software of the apparatus does not have to be modified.

### BRIEF DESCRIPTION OF THE DRAWINGS

FIG. 1 is a block diagram showing an exemplary configuration of a mode switching unit provided in a semiconductor chip of a semiconductor device in accordance with a first embodiment of the present invention.

FIG. 2 is a conceptual diagram showing a cross-sectional structure of the semiconductor device in accordance with the first embodiment.

FIG. 3 is a conceptual diagram showing a rear side of the semiconductor device in accordance with the first embodiment.

FIG. 4 is a conceptual diagram for illustrating the condition of solder balls being mounted on a package in the semiconductor device in accordance with the first embodiment and operation of detachment of a solder ball from the package.

FIG. 5 is a block diagram showing an exemplary configuration of the mode switching unit when a plurality of test modes are needed in the first embodiment.

FIG. 6 is a block diagram showing an exemplary configuration of the mode switching unit when a detection pad is connected to a via hole for a ground voltage in the first embodiment.

FIG. 7 is a block diagram showing an exemplary configuration of a mode switching unit provided in a semiconductor device in accordance with a second embodiment of the present invention.

FIG. 8 is a block diagram showing an exemplary configuration of the mode switching unit in accordance with the second embodiment when a mode via hole is provided to select a function mode depending on the attachment or detachment of a solder ball, and a power supply voltage is applied to the mode via hole when the solder ball is attached.

FIG. 9 is a block diagram showing an exemplary configuration of the mode switching unit in accordance with the second embodiment when a mode via hole is provided to select a function mode depending on the attachment or detachment of a solder ball, and a ground voltage is applied to the mode via hole when the solder ball is attached.

FIG. 10 is a block diagram showing an exemplary configuration of the mode switching unit in accordance with the first embodiment when a function mode is selected depending on the attachment or detachment of a solder ball, and a power supply voltage is applied to the mode via hole when the solder ball is attached.

FIG. 11 is a block diagram showing an exemplary configuration of the mode switching unit in accordance with the first embodiment when a function mode is selected depending on the attachment or detachment of a solder ball, and a ground voltage is applied to the mode via hole when the solder balls are attached.

### DETAILED DESCRIPTION OF THE INVENTION

Hereinafter, semiconductor devices in accordance with embodiments of the present invention will be described with reference the accompanying drawings.

### First Embodiment

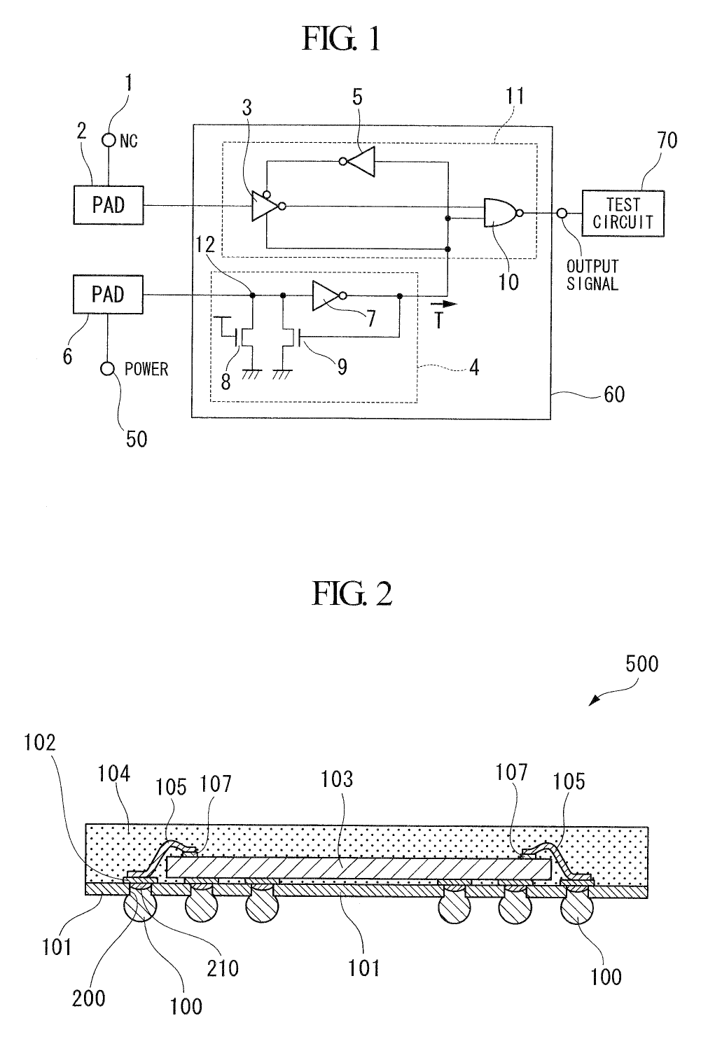

FIG. 1 is a block diagram showing an exemplary configuration of a mode switching unit 60 provided in a semiconductor chip 103 (see FIG. 2) in a semiconductor device 500 (see FIG. 2) in accordance with a first embodiment of the present invention.

Referring to FIG. 1, the mode switching unit 60 includes a mode detector 4 and a mode selector 11. An output signal of the mode switching unit 60 is supplied to a test circuit 70.

The mode detector 4 includes n channel type MOS (metal oxide semiconductor) transistors (hereinafter abbreviated as transistors) 8 and 9 and an inverter (inverting circuit) 7.

A pad (hereinafter also referred to as a detection pad) 6, which is a lead-out electrode formed on the semiconductor chip 103, is connected via a boding wire (corresponding to a bonding wire 105 of FIG. 2) to a via hole (corresponding to a via hole 200 shown in FIG. 2, hereinafter referred to as external power supply via holes) to which power is supplied from the outside of the semiconductor device 500 via a terminal 50. The pad 6 is also connected to an input terminal of the inverter 7 via a wiring line 12.

The transistor 8 has a grounded source, a drain connected to the wiring line 12, and a gate connected to a power supply line and serves as a pull-down resistor of an input terminal of the inverter 7.

The transistor 9 has a grounded source, a drain connected to the wiring line 12, and a gate connected to an output terminal of the inverter 7, and is provided to stabilize the voltage of the input terminal of the inverter 7.

The inverter 7 outputs an L (low) level detection signal T when an H (high) level signal is input to the input terminal thereof, and outputs an H level detection signal T when an L level signal is input to the input terminal thereof.

That is, the mode detector 4 detects whether the level of the voltage applied to the pad 6 is an H level or an L level.

The mode selector 11 includes a clocked inverter 3, an inverter 5, and a NAND circuit 10. A pad 2 for selecting a mode of the semiconductor chip 103 (hereinafter referred to as a mode pad) is connected to an input of the clocked inverter 3. The pad 2 is also connected to a terminal 1 corresponding to a non-connection (NC) pin.

The clocked inverter 3 sets the output terminal thereof to a high-impedance state without transferring a signal from the pad 2 when the detection signal T has an L level, while the clocked inverter 3 inverts the signal from the pad 2 and outputs the inverted signal when the detection signal T has an H level.

The inverter 5 inverts the detection signal T and outputs the inverted detection signal T to an inversion control terminal of the clocked inverter 3.

The NAND circuit 10 outputs an output signal having an L level when both of the detection signal T and a signal output from the output terminal of the clocked inverter 3 are the H level, while the NAND circuit 10 outputs an output signal having an H level irrespective of the level of the output signal of the clocked inverter 3 (accordingly, the signal input from the pad 2) when the detection signal T is an L level.

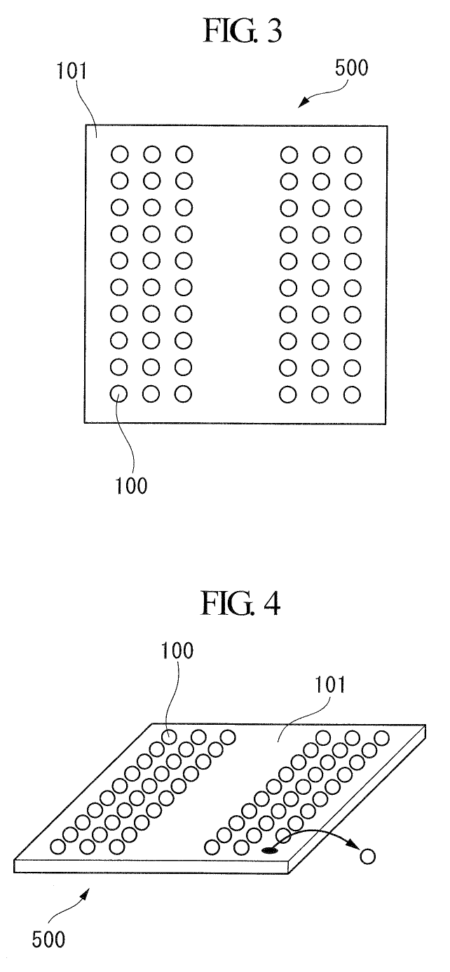

Next, the semiconductor devices 500 in which the semiconductor chip 103 is sealed by a BGA (ball grid array) package will be described with reference to FIG. 2 and FIG. 3. FIG. 2 is a conceptual diagram showing a cross-sectional structure of the semiconductor device 500. FIG. 3 is a plan view showing a rear side of the BGA package, with solder balls 100 arranged in the form of a matrix.

The solder balls 100 are mounted in via holes 200 formed in a resin 101 which is an insulator made of polyimide, or the like.

The resin 101 is provided with a patterned copper foil 102 at a position opposing a position at which a via hole 200 is provided, in a surface (front side) opposing a surface (rear side) on which the solder balls 100 are mounted.

A metal plating 210 is formed on the copper foil 102 in a region exposed by a via hole 200 on the surface (rear side) of the copper foil 102 contacting the resin 101.

In addition, the copper foil 102 is electrically connected to a solder ball 100 via the metal plating 210.

In addition, the copper foil 102 is electrically connected to a pad 107 on the semiconductor chip 103 via the bonding wire 105 made of a metal, such as gold, copper, or the like, on the surface (front side) of the copper foil 102 opposing the surface contacting the resin 101.

In this manner, the solder ball 100 is electrically connected to the pad 107 via the metal plating 210, the copper foil 102, and the boding wire 105.

The semiconductor chip 103 and the boding wire 105 are sealed in a package by a resin 104 and the resin 101. The semiconductor chip 103 includes a test circuit (not shown) having a plurality of function modes and a circuit constituting the mode switching unit 60 shown in FIG. 1.

It should be noted that in the structure as described above, the via hole 200 corresponding to the mode pad (hereinafter referred to as a mode via hole) is preferably provided in the circumference of the solder ball arrangement (accordingly, via hole arrangement) shown in FIG. 3 to facilitate input of a signal to the mode via hole.

That is, in order to input the signal to the mode via hole, the mode via hole is connected to a lead wire through which a signal for selecting modes are input.

For this reason, when the semiconductor device 500 is remounted onto a substrate (not shown) after the lead wire is connected to the mode via hole, provision of the lead wire connected to the via hole arranged in the circumference of the via hole arrangement may facilitate mounting of the semiconductor device 500 on the substrate.

Next, a process for testing an apparatus in accordance with the present embodiment will be described.

For example, a pad 107 connected to one of the plurality of solder balls 100 functioning as power supply terminals of the BGA package is formed as the pad 6 (detection pad), not a power supply pad. It should be noted that the terminal 50 shown in FIG. 1 corresponds to the copper foil 102 connected to the detection pad.

At this time, as shown in FIG. 2, a solder ball 100 is interposed between a power supply terminal (not shown) of the substrate and a plating 210 in a via hole 200 corresponding to the detection pad (hereinafter referred to as a detection via hole). Accordingly, an H level voltage is applied to the pad 6, and as a result, an H level signal is output from the NAND circuit 10. This allows the test circuit 70 connected to the mode switching unit 60 to go into a normal operation mode, not a test mode.

In addition, a via hole 200 functioning as the mode via hole is also formed. In this case, unlike the structure as shown in FIG. 2, the plating 210 is exposed from the via holes 200 without a solder ball 100 attached to the via hole 200. It should be noted that the pad 107 corresponding to the mode pad corresponds to the pad 2 shown in FIG. 1, and the copper foil 102 corresponding to this mode pad corresponds to the terminal 1 shown in FIG. 1.

If the semiconductor device 500 mounted in an apparatus is defective in operation, the semiconductor device 500 is separated from the apparatus once, a solder ball 100 corresponding to a detection via hole is detached from the semiconductor device 500 as shown in FIG. 4 to place the via hole 200 in an exposed state, and then the semiconductor device 500 is remounted onto the apparatus.

As a result, a voltage is no longer applied to the pad 6 because the solder ball 100 interposed between the power supply terminal of the substrate and the plating 210 in the via hole 200 does not exist. Accordingly, the input terminal of the inverter 7 goes into an L level by the transistor 8 and the detection signal T goes into an H level.

Accordingly, by inputting an L level signal to a mode via hole as a signal for selecting a mode, the output of the clocked inverter 3 goes into an H level, an L level signal is output from the NAND circuit 10, and the test circuit 70 connected to the mode switching unit 60 transitions from the normal operation mode to the test mode.

For example, if an internal power supply voltage is increased by 0.1 V in the test mode, the apparatus is operated in a state where the power supply voltage of the semiconductor device 500 is increased by 0.1 V.

When the semiconductor device 500 is operated in the state where the power supply voltage thereof is increased by 0.1 V, it can be determined that it is required to increase the internal power supply voltage of the semiconductor device 500 by 0.1 V to normally operate the semiconductor device 500 in the apparatus.

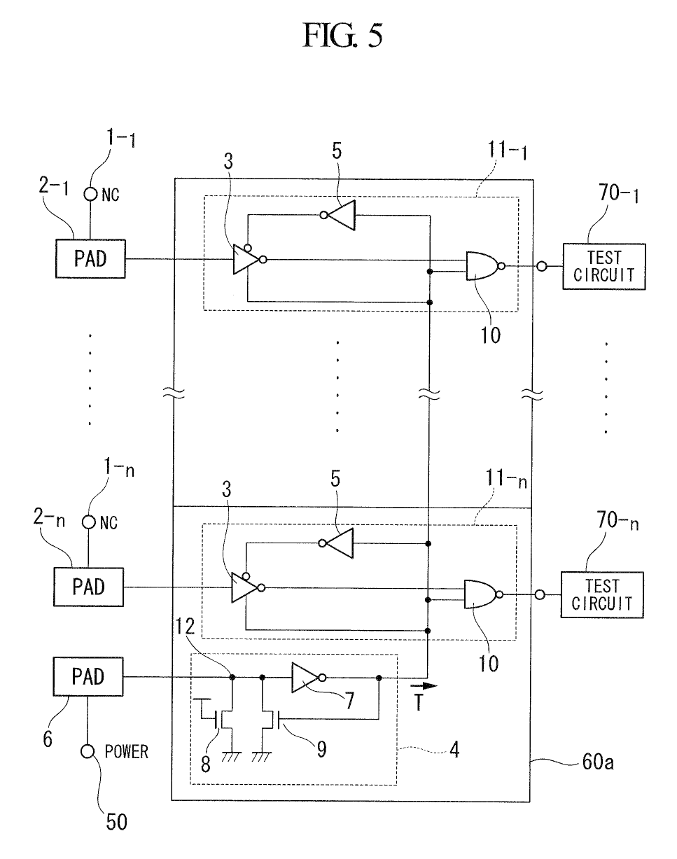

In the case of needing a plurality of test modes, a plurality of mode pads (i.e., pads 2-1 to 2-n respectively connected to terminals 1-1 to 1-n, where n is an integer of 2 or more) are provided as shown in FIG. 5. Moreover, via holes 200 functioning as mode via holes corresponding to these mode pads are also provided. Furthermore, in the structure shown in FIG. 2, platings 210 are exposed from the via holes 200 without solder balls 100 mounted in the via holes 200.

In addition, mode selectors 11-1 to 11-n, each of which has the same structure as the mode selector 11 shown in FIG. 1, are provided for the respective mode pads, as shown in a mode switching unit 60a of FIG. 5. In such a structure, one of test circuits 70-1 to 70-n arranged at the next stages of the mode selectors 11-1 to 11-n is operated, and by using combinations of H or L levels of voltages input to the mode pads, the following apparatus test can be conducted which cannot be conducted in a tester.

Examples of test modes in the apparatus test are shown as follows for a case where a dynamic RAM (random access memory) is employed as the semiconductor device 500.

A. A voltage value (for example, a voltage Vpp) of one of a plurality of internal power sources is varied.

B. Adjustment of a start timing of a main amplifier is made.

C. Adjustment of a start timing of a sense amplifier is made.

D. Some dynamic RAMs have the function of reducing current consumption by adjusting the refresh cycle depending on temperature. If the adjustment of the refresh cycle is not well made, a setting operation of stopping this function is conducted.

It should be noted that although FIG. 5 shows that output signals from the mode selectors 11-1 to 11-n are input to the respective test circuits 70-1 to 70-n, the present invention is not limited thereto. For example, a structure may be employed in which an output signal of one of the mode selectors is supplied to a part or all of the test circuits 70-1 to 70-n. Alternatively, a structure may be employed in which a part or all of n output signals of the mode selectors 11-1 to 11-n are supplied to a particular test circuit, and this test circuit sets a plurality of test modes in accordance with a combination of these output signals. Moreover, these structures may be properly combined.

In the above, the state where the solder ball is interposed between the power supply terminal of the substrate and the plating 210 in the detection via hole is the normal operation mode while the state where the solder ball is detached is the test mode. On the contrary, the state where the solder ball is detached may be the normal operation mode while the state where the solder ball is interposed may be the test mode.

In addition, although it is shown in the above that the detection pad is connected to the via hole for power supply (the aforementioned external power supply via hole), the detection pad may be connected to a via hole for ground voltage (GND).

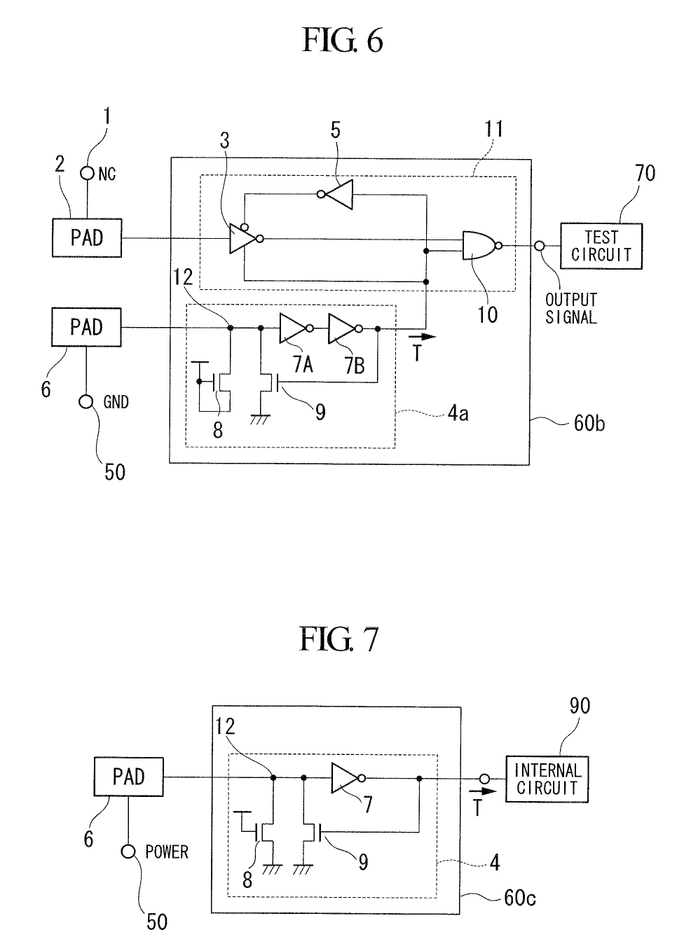

In this case, as shown in a mode detector 4a constituting a mode switching unit 60b shown in FIG. 6, the transistor 8 functions as a pull-up resistor by connecting the drain and the gate of the transistor 8 to the power supply line and the source of the transistor 8 to the wiring line 12.

In addition, the inverter 7 is replaced with an inverter 7A and an inverter 7B which are connected in series. This allows achieving processes in the test mode in the same manner as those by the configuration of FIG. 1.

Specifically, if the solder ball 100 is not interposed between the power supply terminal of the substrate and the plating 210 in the via hole 200 functioning as the detection via hole, an H level voltage is applied to the input terminal of the inverter 7A, and thus the detection signal T goes into an H level. Accordingly, by inputting an L level signal as a signal for selecting a mode to the mode via hole, the output of the clocked inverter 3 goes into an H level, and thus an L level signal is output from the NAND circuit 10, thereby placing the test circuit 70 into the test mode, not the normal operation mode.

On the other hand, if the solder ball 100 is interposed between the power terminal of the substrate and the plating 210 in the via hole 200 functioning as the detection via hole, an L level voltage is applied to the input terminal of the inverter 7A, and thus an H level signal is output from the NAND circuit 10, thereby switching the test circuit 70 to the normal operation mode, not the test mode.

With the above described structure, if the semiconductor device 500 mounted in an apparatus is defective, failure analysis may be made in the apparatus in a state where the apparatus is operated in the normal operation mode (that is, without modifying software) even for failure which was difficult to be analyzed in a tester.

In addition, since operation conditions required for the semiconductor device 500 can be detected in the apparatus, it is possible to realize feedback of performance required for the semiconductor device 500 mounted on the substrate, thereby reducing the failure of semiconductor devices in the market.

### Second Embodiment

Next, a process of switching a plurality of function modes of the semiconductor chip 103 depending on the presence or absence of a solder ball in the same way as the first embodiment will be described.

For example, in the case of card type electronic devices, there is a need to prepare separate semiconductor chips in compliance with respective specifications, such as command systems to control an internal circuit 90 (FIG. 7), since the command systems are different from each other even when the specifications of the command transfer protocol are the same.

To meet such a need, semiconductor chips for card type electronic devices which can deal with different command systems (for example, both of a command system A and a command system B) are prepared.

In addition, like the first embodiment, a detection via hole and a detection pad are provided, and the internal circuit 90 switches the command systems depending on whether or not a solder ball is mounted. That is, the internal circuit 90 operates in accordance with the command system A if the solder ball is mounted, and in accordance with the command system B if the solder ball is not mounted.

In this case, as shown in FIG. 7, a mode switching unit 60c including only the mode detector 4 without the mode selector 11 switches function modes (that is, switches between the command system A and the command system B) depending on a voltage level of the detection signal T.

With the above structure, if the semiconductor device is mounted on a substrate which includes an internal circuit employing the command system A as a specification with the solder ball attached to the detection via hole, the detection signal T goes into an L level. On the other hand, if the semiconductor device is mounted on a substrate which includes an internal circuit employing the command system B as a specification with the solder balls detached from the detection via hole, the detection signal T goes into an H level. In this manner, one semiconductor chip can have two uses and the type of semiconductor chip can be selected depending on the presence or absence of a solder ball, which can result in reduction in production costs of semiconductor chips.

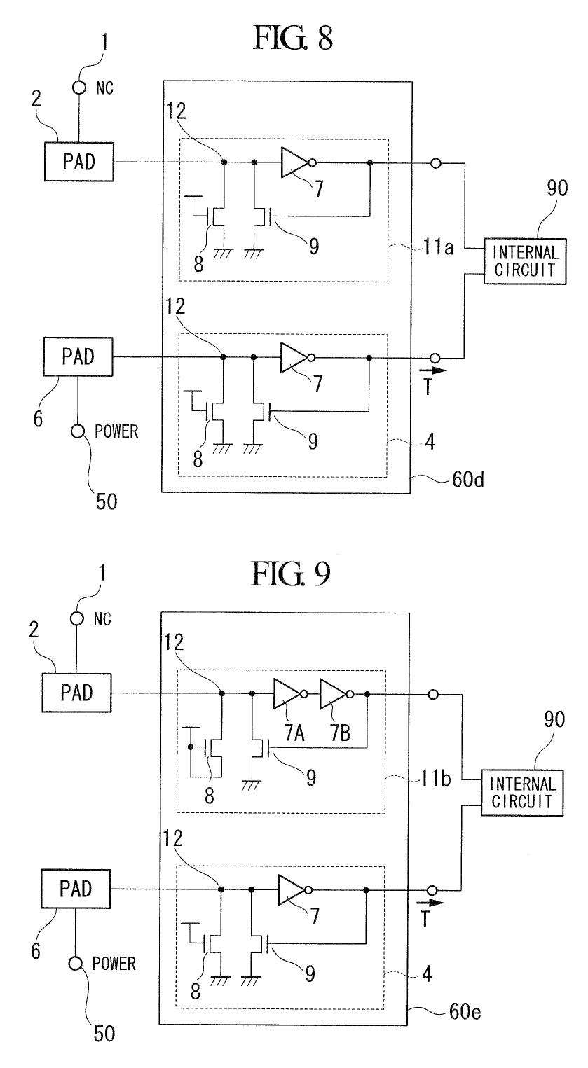

In addition, in order to select a plurality of function modes, as shown in FIG. 8, a mode switching unit 60d may include, in addition to the mode detector 4, one or more mode selectors 11a having the same structure as the mode detector 4, and, like the first embodiment, may also include one or more mode via holes and one or more mode pads (that is, a pad 2). In addition, the pad 2 is connected to the mode selector 11a and an output of the mode selector 11a is input to the internal circuit 90.

FIG. 8 shows the configuration where a power supply voltage is applied to the mode via hole by attaching the solder ball to the mode via hole. If the solder ball is not attached to the mode via hole, an L level signal is input to the input terminal of the inverter 7 and an H level signal is input as a mode selection signal to the internal circuit 90. On the other hand, if the solder ball is attached to the mode via hole, an H level signal is input to the input terminal of the inverter 7 and an L level signal is input as a mode selection signal to the internal circuit 90. It should be noted that FIG. 8 shows an example in which one mode selector 11a, one mode via hole, and one mode pad are provided.

In addition, if a ground voltage is applied to the mode via hole by attaching the solder ball to the mode via hole, as shown in FIG. 9, a mode switching unit 60e includes a mode selector 11b having the same structure as the mode detector 4a shown in FIG. 6, instead of the mode selector 11a shown in FIG. 8. If the solder ball is not attached to the mode via hole, an H level signal is input to the input terminal of the inverter 7, and an H level signal is input as a mode selection signal to the internal circuit 90. On the other hand, if the solder ball is attached to the mode via hole, an L level signal is input to the input terminal of the inverter 7, and an L level signal is input as a mode selection signal to the internal circuit 90. It should be noted that FIG. 9 shows an example in which one mode selector 11b, one mode via hole, and one mode pad are provided.

It should be noted that, in the first embodiment, like those described in the second embodiment, a plurality of function modes may be selected depending on attachment or detachment of a solder ball.

In this case, if a power supply voltage is applied to the mode via hole by attaching the solder ball to the mode via hole, as shown in a mode switching unit 60f of FIG. 10, the input terminal of the clocked inverter 3 is pulled down using a transistor 13. It should be noted that FIG. 10 shows an example in which one mode selector 11, one mode via hole, and one mode pad are provided. If the solder ball is not attached to the mode via hole, an L level signal is input to the input terminal of the clocked inverter 3. On the other hand, if the solder ball is attached to the mode via hole, an H level signal is input to the input terminal of the clocked inverter 3.

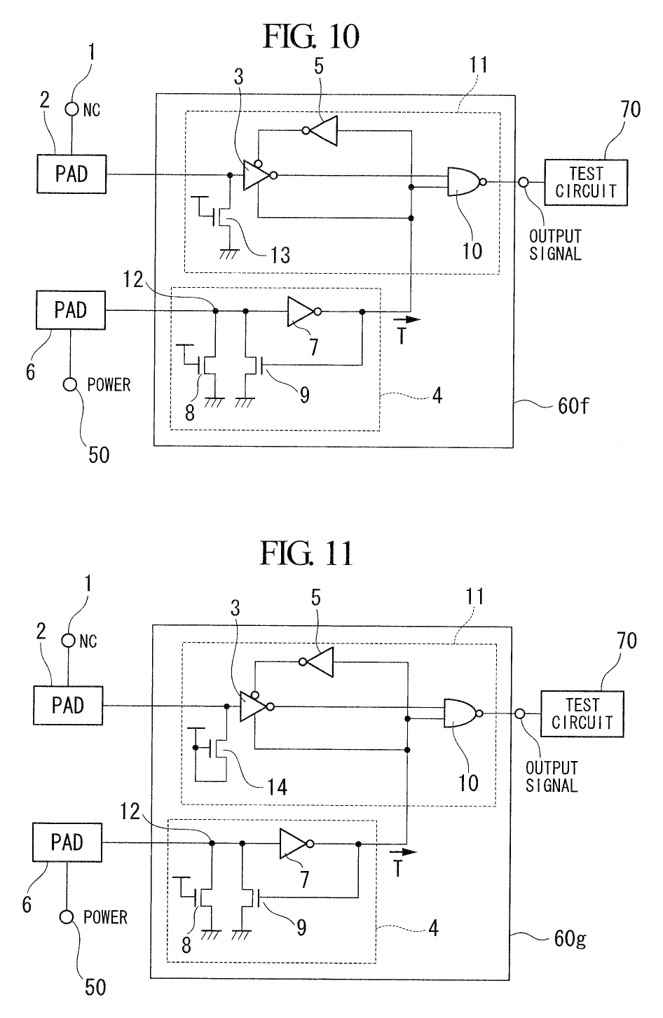

In addition, if a ground voltage is applied to the mode via hole by attaching the solder ball to the mode via hole, as shown in a mode switching unit 60g of FIG. 11, the input terminal of the clocked inverter 3 is pulled up using a transistor 14. It should be noted that FIG. 11 shows an example in which one mode selector 11, one mode via hole, and one mode pad are provided. If the solder ball is not attached to the mode via hole, an H level signal is input to the input terminal of the clocked inverter 3. On the other hand, if the solder ball is attached to the mode via hole, an L level signal is input to the input terminal of the clocked inverter 3.

While preferred embodiments of the present invention have been described and illustrated above, it should be understood that these are exemplary of the present invention and are not to be considered as limiting. Additions, omissions, substitutions, and other modifications can be made without departing from the gist or scope of the present invention. Accordingly, the present invention is not to be considered as being limited by the foregoing description, and is only limited by the scope of the appended claims.

What is claimed is:

1. A semiconductor device using a ball grid array package, comprising:
a semiconductor chip that is provided within the semiconductor device and has a pad;
a detection via hole connected to the pad;
a solder ball that is attachable to and detachable from the detection via hole and connects or disconnects a power supply electrode of a substrate on which the semiconductor device is mounted and the detection via hole in correspondence to attachment of the solder ball to the detection via hole or detachment of the solder ball from the detection via hole, respectively; and
a mode switching unit that detects a voltage level of the pad connected to the detection via hole and switches a plurality of function modes in the semiconductor device depending on the voltage level.

2. The semiconductor device as recited in claim 1, wherein the detection via hole is an external power supply via hole to which power is supplied from the outside of the package.

3. The semiconductor device as recited in claim 1, further comprising a mode via hole for function mode selection,
wherein the mode switching unit switches the function modes by selecting one of the plurality of function modes in accordance with a voltage level of the mode via hole.

4. The semiconductor device as recited in claim 3, wherein the mode via hole is a via hole for non-connection.

5. The semiconductor device as recited in claim 3, wherein the mode via hole is provided in the circumference of the semiconductor device.

6. A mode switching method for a semiconductor device using a ball grid array package, comprising:
attaching or detaching a solder ball to or from a detection via hole connected to a pad of a semiconductor chip provided within the semiconductor device, and connecting or disconnecting a power electrode of a substrate on which the semiconductor device is mounted and the detection via hole; and
detecting a voltage level of the detection via hole, and switching a plurality of function modes in the semiconductor device depending on the voltage level.
